(19) United States
(12) Patent Application Publication
(10) Pub. No.: US 2012/0265465 A1
(43) Pub. Date: Oct. 18, 2012

(54) SIGNAL ANALYZING SYSTEM AND METHOD USING CONTINUOUS SHIFTED TRANSFORM

(76) Inventor: Chin-Shiong TSAI, Taoyuan Hsien (TW)

(21) Appl. No.: 13/427,368

(22) Filed: Mar. 22, 2012

(30) Foreign Application Priority Data
Apr. 14, 2011 (TW) 100112897

(51) Int. Cl. G06F 15/00; G01N 29/46; G01R 23/167

(52) U.S. Cl. 702/77; 702/190

(57) ABSTRACT

A signal analyzing system is provided. The signal analyzing system includes a band pass filter (BPF), a sampling unit and a continuous shifted transform (CST) unit. The BPF filters an input signal to obtain a filtered signal. The sampling unit samples the filtered signal to obtain a discrete signal according to a sampling frequency. The CST unit obtains a first frequency spectrum according to the N discrete signals that are sampled continuously, and obtains a second frequency spectrum according to a (N+1)^{th} discrete signal and the first frequency spectrum. Each of the first and second spectra includes N Fourier transform operation results.

### CROSS REFERENCE TO RELATED APPLICATIONS

This application claims priority of Taiwan Patent Application No. 100112897, filed on Apr. 14, 2011, the entirety of which is incorporated by reference herein.

### BACKGROUND OF THE INVENTION

1. Field of the Invention

The invention relates to a signal analyzing system and method, and more particularly to a signal analyzing system and method using continuous shifted transform (CST).

2. Description of the Related Art

Under long operating session, a breakdown of internal components of a machine will occur due to abrasion. Vibration forces can result in failure or inefficient operation of a machine equipped with a motor. For example, in a computer numerical control (CNC) processing machine, an upper computer may provide a position common to a multi-axis alternating current (AC) servo driver, to drive a motor, and then a platform of the processing machine is moved by a guide screw and rail. However, mechanical loss, lubrication conditions or misalignments will affect the normal operations of the processing machine. Therefore, vibrations caused by imbalance (e.g. irregular vibrations) will significantly harm the engine assembly.

Once an imbalancing problem has been discovered, it is necessary to perform vibration analysis to diagnose and correct the problem. So, the machine has to be taken out of service and analyzed which typically involves mounting the engine on a test stand. In general, an accelerometer (G sensor) is used to obtain a vibration signal of a machine, and then the vibration signal is analyzed, so as to obtain health diagnostic/operating conditions of the machine.

A discrete short time Fourier transform (STFT) is usually used to transform the vibration signal for analyzing the frequency components of the vibration signal. For continuity between the frequency spectrums, various window functions are applied to the discrete short time Fourier transforms. If no window function is used, discontinuous portions are formed at the two extremities of the data points of the obtained vibration signal, such that white noise is formed in the frequency spectrum after transformation. However, for N points discrete short time Fourier transform, N multiplication operations are used to perform the window functions and samplings of the vibration signal. Moreover, selecting a window function from various window functions is based on a bandwidth of the vibration signal. For example, a lower frequency signal will cause a larger attenuation in intensity, so a window function will cause a distortion for low frequency components. In addition, N×log₂N multiplication operations are needed to complete a discrete short time Fourier transform, that will occupy a large number of operation resources (e.g. multipliers, registers and so on) and operation time.

### BRIEF SUMMARY OF THE INVENTION

A signal analyzing system and method using continuous shifted transform (CST) are provided. An embodiment of a signal analyzing system is provided. The signal analyzing system comprises: a band pass filter, filtering an input signal to obtain a filtered signal; a sampling unit, sampling the filtered signal to obtain a discrete signal according to a sampling frequency; and a continuous shifted transform unit, obtaining a first frequency spectrum according to the N discrete signals that are sampled continuously, and obtaining a second frequency spectrum according to a (N+1)^{th} discrete signal and the first frequency spectrum. Each of the first and second frequency spectrums comprises N Fourier transform operation results.

Furthermore, an embodiment of a signal analyzing method is provided. an input signal is filtered to obtain a filtered signal. The filtered signal is sampled to obtain a discrete signal. A first frequency spectrum is obtained according to the N discrete signals that are sampled continuously. A second frequency spectrum is obtained according to a (N+1)^{th} discrete signal and the first frequency spectrum. Each of the first and second frequency spectrums comprises N Fourier transform operation results.

A detailed description is given in the following embodiments with reference to the accompanying drawings.

### BRIEF DESCRIPTION OF DRAWINGS

The invention can be more fully understood by reading the subsequent detailed description and examples with references made to the accompanying drawings, wherein:

FIG. 1 shows a signal analyzing system according to an embodiment of the invention;

FIG. 2 shows a schematic illustrating a continuous shifted transform operation of frequency spectrums according to an embodiment of the invention; and

FIG. 3 shows a time-frequency spectrum of the input signal x₀(t) according to an embodiment of the invention.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

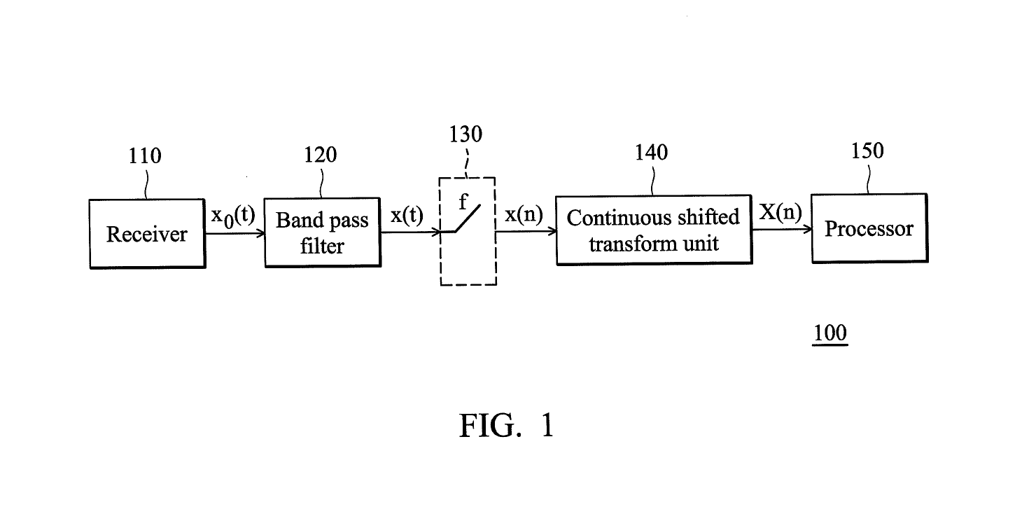

FIG. 1 shows a signal analyzing system 100 according to an embodiment of the invention. The signal analyzing system 100 comprises a receiver 110, a band pass filter (BPF) 120, a sampling unit 130, a continuous shifted transform unit 140 and a processor 150. In the embodiment, the receiver 110 is an accelerometer for detecting a vibration state of an electronic apparatus (e.g. a machine) to provide an input signal x₀(t). Next, the band pass filter 120 filters the input signal x₀(t) to obtain a filtered signal x(t). Next, the sampling unit 130 samples the filtered signal x(t) according to a sampling frequency f, to obtain a discrete signal x(n). Next, the continuous shifted transform unit 140 uses a Continuous Shifted Transform (CST) algorithm to obtain a continuous shifted frequency spectrum X(n) according to the continuous received discrete signals x(n), wherein details of execution of the CST algorithm are described below. Next, the processor 150 obtains a time-frequency spectrum of the input signal x₀(t) according to the continuous received frequency spectrums X(n), and the processor 150 further analyzes the time-frequency spectrum of the input signal x₀(t) to determine whether a frequency signal having a significant intensity exists. If yes, the processor 150 further analyzes whether the frequency signal is induced due to component damage (such as damage to an inner or outer ring of a bearing or ball damage) or self resonance of the electronic apparatus. In the embodiment, the band pass filter 120 filters out the frequency components that exceed one half of the sampling frequency f and the frequency components smaller than 2/N times that of the sampling frequency f, from the input signal x₀(t), i.e. 2f/N□ x(t) □f/2. Furthermore, by using the band pass filter 120 to filter the input signal x₀(t), the continuous shifted transform unit 140 performs a frequency spectrum transform operation without a window function, thus decreasing computations for the frequency spectrum transform operation.

Discrete Fourier Transform (DFT) is a specific kind of discrete transform operation in the frequency and time domains, used in Fourier analysis. For N point discrete signals x(n), i.e. {x(n)}_{0≦n<N}, a DFT X(n) is given by the following equation (1):

X(n)=Σⱼ₌₁^{N}x(n)ω_{N}^{(j-1)(n-1)} (1)

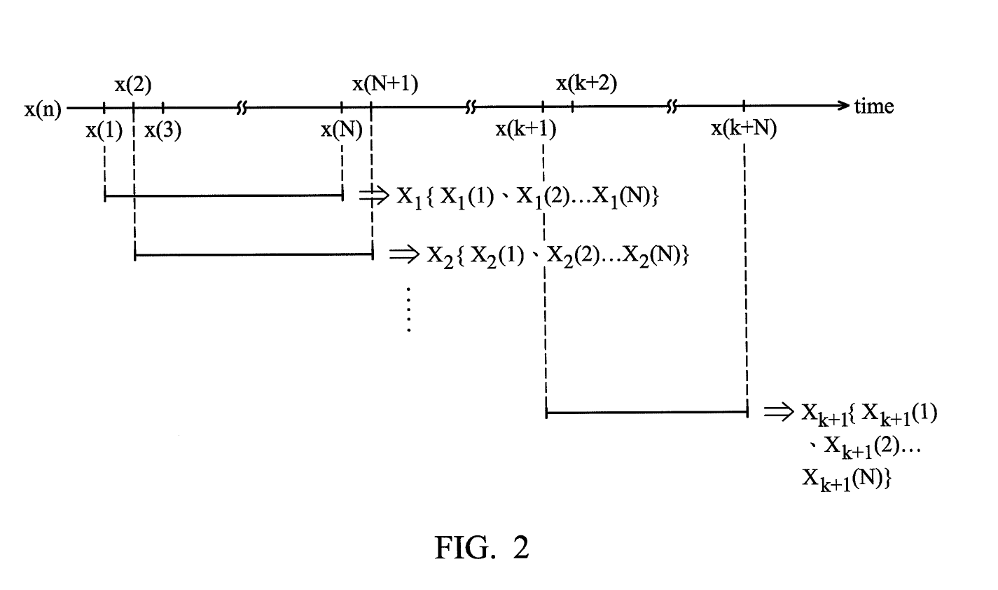

, where ω_{N} represents a root of unity e−2πi/N, e represents a base number of natural logarithm, and i represents an imaginary number unit (i=\sqrt{−1}). FIG. 2 shows a schematic illustrating a continuous shifted transform operation of frequency spectrums according to an embodiment of the invention. In FIG. 2, the signals x(1), x(2), . . . , x(N), x(N+1), . . . , x(N+k) are the discrete signals x(n) that are continuously provided by the sampling unit 130 of FIG. 1. When performing a Fourier transform operation to the signals from x(1) to x(N) simultaneously, a first frequency spectrum X₁ is obtained, wherein the first frequency spectrum X₁ comprises the N Fourier transform operation results X₁(1), X₁(2), . . . , and X₁(N) that represent the Fourier transform operations of the signals x(1), x(2), . . . , and x(N), respectively. Similarly, when performing the Fourier transform operation to the signals from x(2) to x(N+1) simultaneously, a second frequency spectrum X₂ is obtained, wherein the second frequency spectrum X₂ comprises the Fourier transform operation results X₂(1), X₂(2), . . . , and X₂(N) that represent the Fourier transform operations of the signals x(2), x(3), . . . , and x(N+1), respectively. Therefore, when performing the Fourier transform operation to the signals x(k+1), x(k+2), . . . , x(k+N) simultaneously, a (k+1)^{th} frequency spectrum Xₖ₊₁ is obtained, wherein the (k+1)^{th} frequency spectrum Xₖ₊₁ comprises the Fourier transform operation results Xₖ₊₁(1), Xₖ₊₁ (2), . . . , and Xₖ₊₁(N) that represent the Fourier transform operations of the signals x(k+1), x(k+2), . . . , and x(k+N), respectively.

For each of the frequency spectrums from X₁ to Xₖ₊₁, N×log₂N multipliers are needed to obtain the frequency spectrum when a fast Fourier transform (FFT) is used to perform the transformation operation. Therefore, during each sampling time (i.e. 1/sampling frequency f)), using a FFT to obtain an instantaneous frequency spectrum will occupy a large number of operation resources (e.g. multipliers, registers and so on) and operation time.

The continuous shifted transform operation of the invention is described below. In order to simplify the description, N=4. First, according to the DFT of the equation (1), the four Fourier transform operation results X₁(1), X₁(2), X₁(3) and X₁(4) of the first frequency spectrum X₁ are given by the following equations:

X₁(1)=x(1)ω_{N}⁰+x(2)ω_{N}⁰+x(3)ω_{N}⁰+x(4)ω_{N}⁰

X₁(2)=x(1)ω_{N}⁰+x(2)ω_{N}¹+x(3)ω_{N}²+x(4)ω_{N}³

X₁(3)=x(1)ω_{N}⁰+x(2)ω_{N}²+x(3)ω_{N}⁴+x(4)ω_{N}⁶

X₁(4)=x(1)ω_{N}⁰+x(2)ω_{N}³+x(3)ω_{N}⁶+x(4)ω_{N}⁹ frequency spectrum X₁.

Next, according to the DFT of the equation (1), the four Fourier transform operation results X₂(1), X₂(2), X₂(3) and X₂(4) of the second frequency spectrum X₂ are given by the following equations:

X₂(1)=x(2)ω_{N}⁰+x(3)ω_{N}⁰+x(4)ω_{N}⁰+x(5)ω_{N}⁰

X₂(2)=x(2)ω_{N}⁰+x(3)ω_{N}¹+x(4)ω_{N}²+x(5)ω_{N}³

X₂(3)=x(2)ω_{N}⁰+x(3)ω_{N}²+x(4)ω_{N}⁴+x(5)ω_{N}⁶

X₂(4)=x(2)ω_{N}⁰+x(3)ω_{N}³+x(4)ω_{N}⁶+x(5)ω_{N}⁹ frequency spectrum X₂.

Next, by applying the frequency transform operation results of the first frequency spectrum X₁ into the second frequency spectrum X₂, the Fourier transform operation results X₂(1), X₂(2), X₂(3) and X₂(4) of the second frequency spectrum X₂ are re-given by the following equations:

$${X}_{2} ( 1 ) = {X}_{1} ( 1 ) - x ( 1 ) + x ( 5 )$$

$$\begin{matrix}{X}_{2} ( 2 ) = ( {X}_{1} ( 2 ) - x ( 1 ) ) {ω}_{N}^{- 1} + x ( 5 ) {ω}_{N}^{3} \\ = ( {X}_{1} ( 2 ) - x ( 1 ) + x ( 5 ) ) {ω}_{N}^{- 1} \\ {X}_{2} ( 3 ) = ( {X}_{1} ( 3 ) - x ( 1 ) ) {ω}_{N}^{- 2} + x ( 5 ) {ω}_{N}^{6} \\ = ( {X}_{1} ( 3 ) - x ( 1 ) + x ( 5 ) ) {ω}_{N}^{- 2} \\ {X}_{2} ( 4 ) = ( {X}_{1} ( 4 ) - x ( 1 ) ) {ω}_{N}^{- 3} + x ( 5 ) {ω}_{N}^{9} \\ = ( {X}_{1} ( 4 ) - x ( 1 ) + x ( 5 ) ) {ω}_{N}^{- 3}\end{matrix} \\ -- - frequency spectrum {X}_{2} .$$

Therefore, a new frequency spectrum X₂ is obtained by adding a discrete signal x(5) into the frequency spectrum X₁ that was obtained previously and removing a discrete signal x(1) from the frequency spectrum X₁. Furthermore, as eight multiplication operations (i.e. 4×log₂4) are used to perform a fast Fourier transform operation, only three multiplication operations (i.e. 4-1) are used to perform the continuous shifted transform operation, to obtain the frequency spectrum X₂.

As described above, according to the continuous shifted transform operation of the invention, a k^{th} frequency spectrum, a discrete signal x(k) and a discrete signal s(k+N) are used to obtain a (k+1)^{th} frequency spectrum Xₖ₊₁ shown in the following equation (2):

$$\begin{matrix}{X}_{k + 1} ( j ) = ( {X}_{k} ( j ) - x ( k ) ) {ω}_{N}^{1 - j} + x ( k + N ) {ω}_{N}^{( j - 1 ) ( N - 1 )} \\ = ( {X}_{k} ( j ) - x ( k ) + x ( k + N ) ) {ω}_{N}^{1 - j}\end{matrix} \qquad ( 2 )$$

, where j=1, 2, . . . , and N. When j=1, ω_{N} is equal to 1, thus no multiplication operation is needed for the Fourier transform Xₖ₊₁(1). Therefore, only N−1 multiplication operations are needed to perform a continuous shifted transform operation for the (k+1)^{th} frequency spectrum Xₖ₊₁. Furthermore, for the discrete signal x(n), the continuous shifted transform operation of the invention only shifts one sampling point at a time, thus the frequency spectrum successively varies. Furthermore, compared to the fast Fourier transform operation, less multiplication operations are needed for the continuous shifted transform operation. For example, if N=1024, a fast Fourier transform operation needs 10240 multiplication operations, while a continuous shifted transform operation only needs 1023 multiplication operations.

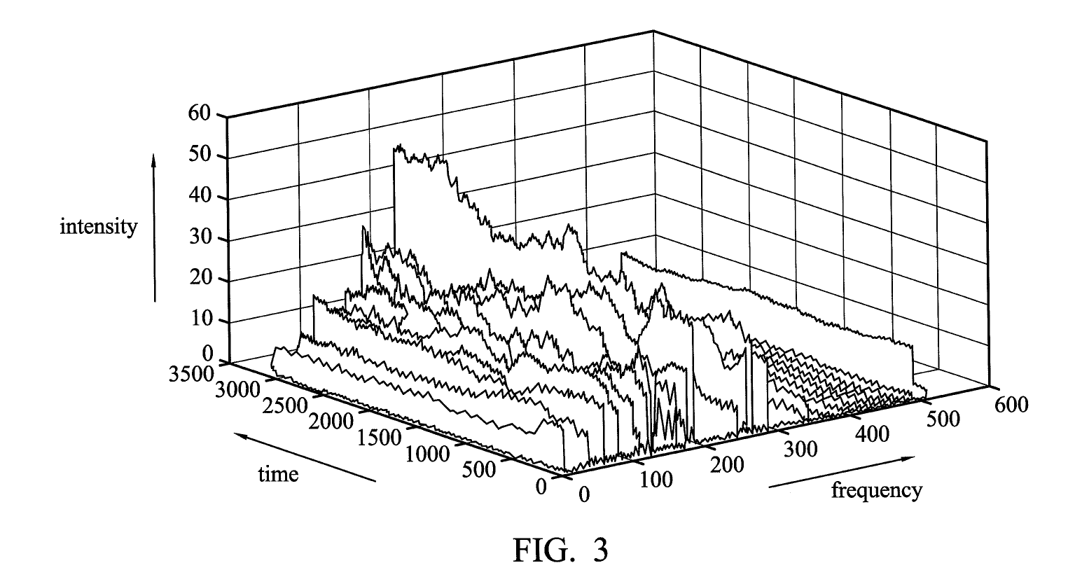

Referring back to FIG. 1, if an initial input signal x₀(t) received by the receiver 110 is zero, for example no vibration is present at an initial state, the first frequency spectrum X₁ is also zero, thus the signal analyzing system 100 directly performs a continuous shifted transform operation to obtain a next frequency spectrum X₂. On the contrary, if the initial input signal x₀(t) is not equal to zero, the continuous shifted transform unit 140 first performs fast Fourier transform opeartions to obtain the first frequency spectrum X₁ of the discrete signals from x(1) to x(N), and then the continuous shifted transform unit 140 performs continuous shifted transform operations to obtain sequential frequency spectrums X₂, X₃, . . . , and Xₖ₊₁. Next, the processor 150 obtains a time-frequency spectrum of the input signal x₀(t) according to the continuous shifted frequency spectrums X₁, X₂, . . . , Xₖ₊₁, as shown in FIG. 3. In FIG. 3, the intensity of some frequencies will be changed with time. Therefore, by analyzing the bands with high intensity of the frequency intensity distribution, the processor 150 further determines whether the components of the electronic apparatus are damaged, so as to provide operating conditions (e.g. health diagnostics) of the electronic apparatus to a user for reference.

The signal analyzing system 100 may be implemented in a machine system or other independent apparatus, and may be executed in a hardware or software manner. According to the embodiments of the invention, using the continuous shifted transform operation can result in rapid continuous shifted frequency spectrums, so as to obtain a corresponding time-frequency spectrum immediately. According to the obtained time-frequency spectrum, the related components corresponding to a rotational speed of a machine system and the other non-related components are separated by the processor 150, thus obtaining health diagnostics of the machine system.

Furthermore, the signal analyzing system 100 of the invention may also be implemented in a communication apparatus. In one embodiment, the receiver 110 may be a microphone, and the input signal x₀(t) is an audio signal received by the microphone. In another embodiment, the receiver 110 may be a radio frequency (RF) module, which provides the input signal x₀(t) corresponding to an RF signal from an antenna, so as to perform a signal analysis for the processor 150.

Data transmission methods, or certain aspects or portions thereof, may take the form of a program code (i.e., executable instructions) embodied in tangible media, such as floppy diskettes, CD-ROMS, hard drives, or any other machine-readable storage medium, wherein, when the program code is loaded into and executed by a machine, such as a computer, the machine thereby becomes an apparatus for practicing the methods. The methods may also be embodied in the form of a program code transmitted over some transmission medium, such as electrical wiring or cabling, through fiber optics, or via any other form of transmission, wherein, when the program code is received and loaded into and executed by a machine, such as a computer, the machine becomes an apparatus for practicing the disclosed methods. When implemented on a general-purpose processor, the program code combines with the processor to provide a unique apparatus that operates analogously to application specific logic circuits.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A signal analyzing system, comprising:
a band pass filter, filtering an input signal to obtain a filtered signal;
a sampling unit, sampling the filtered signal to obtain a discrete signal according to a sampling frequency; and
a continuous shifted transform unit, obtaining a first frequency spectrum according to the N discrete signals that are sampled continuously, and obtaining a second frequency spectrum according to a (N+1)^{th} discrete signal and the first frequency spectrum,
wherein each of the first and second frequency spectrums comprises N Fourier transform operation results.

2. The signal analyzing system as claimed in claim 1, wherein the continuous shifted transform unit further obtains a (k+1)^{th} frequency spectrum according to a (k+N)^{th} discrete signal and a k^{th} frequency spectrum, wherein each of the k^{th} and (k+1)^{th} frequency spectrums comprises N Fourier transform operation results.

3. The signal analyzing system as claimed in claim 2, further comprising:
a processor coupled to the continuous shifted transform unit, obtaining a time-frequency spectrum according to each frequency spectrum from the first frequency spectrum to the (k+1)^{th} frequency spectrum, and obtaining a frequency intensity distribution of the input signal according to the time-frequency spectrum.

4. The signal analyzing system as claimed in claim 2, wherein the continuous shifted transform unit obtains the N Fourier transform operation results of the second frequency spectrum according to Xₖ₊₁(j)=(Xₖ(j)−x(k)+x(k+N))×ω_{N}^{1-j}, wherein x(k) represents a first discrete signal, x(k+N) represents the (N+1)^{th} discrete signal, ω_{N} represents a root of unity e−2πi/N, Xₖ₊₁(j) represents the second frequency spectrum, and Xₖ(j) represents the first frequency spectrum, where j is from 1 to N.

5. The signal analyzing system as claimed in claim 2, wherein the continuous shifted transform unit obtains the N Fourier transform operation results of the (k+1)^{th} frequency spectrum according to Xₖ₊₁ (j)=(Xₖ(j)−x(k)+x(k+N))×ω_{N}^{1-j}, wherein x(k) represents a (k+1)^{th} discrete signal, x(k+N) represents the (k+N)^{th} discrete signal, ω_{N} represents a root of unity e−2πi/N, Xₖ₊₁(j) represents the (k+1)^{th} frequency spectrum, and Xₖ(j) represents the k^{th} frequency spectrum, where j is from 1 to N.

6. The signal analyzing system as claimed in claim 1, wherein a bandwidth range of the band pass filter is from 2/N times that of the sampling frequency to ½ times that of the sampling frequency.

7. The signal analyzing system as claimed in claim 1, wherein the continuous shifted transform unit performs fast Fourier transform operations on the N discrete signals, to obtain the first frequency spectrum.

8. The signal analyzing system as claimed in claim 1, further comprising:
a receiver, detecting a vibration state of an electronic apparatus, and providing the input signal corresponding to the vibration state to the band pass filter.

9. The signal analyzing system as claimed in claim 1, further comprising:
a receiver, receiving an audio signal or a radio frequency signal, and providing the input signal corresponding to the received signal to the band pass filter.

10. A signal analyzing method, comprising:
filtering an input signal to obtain a filtered signal;
sampling the filtered signal to obtain a discrete signal;
obtaining a first frequency spectrum according to the N discrete signals that are sampled continuously; and
obtaining a second frequency spectrum according to a (N+1)^{th} discrete signal and the first frequency spectrum,
wherein each of the first and second frequency spectrums comprises N Fourier transform operation results.

11. The signal analyzing method as claimed in claim 10, further comprising:
obtains a (k+1)^{th} frequency spectrum according to a (k+N)^{th} discrete signal and a k^{th} frequency spectrum, wherein each of the k^{th} and (k+1)^{th} frequency spectrums comprises N Fourier transform operation results.

12. The signal analyzing method as claimed in claim 11, further comprising:
obtaining a time-frequency spectrum according to each frequency spectrum from the first frequency spectrum to the (k+1)^{th} frequency spectrum; and
obtaining a frequency intensity distribution of the input signal according to the time-frequency spectrum.

13. The signal analyzing method as claimed in claim 11, wherein the N Fourier transform operation results of the second frequency spectrum are obtained according to Xₖ₊₁(j)=(Xₖ(j)−x(k)+x(k+N))×ω_{N}^{1-j}, wherein x(k) represents a first discrete signal, x(k+N) represents the (N+1)^{th} discrete signal, ω_{N} represents a root of unity e−2πi/N, Xₖ₊₁(j) represents the second frequency spectrum, and Xₖ(j) represents the first frequency spectrum, where j is from 1 to N.

14. The signal analyzing method as claimed in claim 11, wherein the N Fourier transform operation results of the (k+1)^{th} frequency spectrum are obtained according to Xₖ₊₁(j)=(Xₖ(j)−x(k)+x(k+N))×ω_{N}^{1-j}, wherein x(k) represents a (k+1)^{th} discrete signal, x(k+N) represents the (k+N)^{th} discrete signal, ω_{N} represents a root of unity e−2πi/N, Xₖ₊₁(j) represents the (k+1)^{th} frequency spectrum, and Xₖ(j) represents the k^{th} frequency spectrum, where j is from 1 to N.

15. The signal analyzing method as claimed in claim 10, wherein the step of obtaining the first frequency spectrum further comprises:
performing fast Fourier transform operations on the N discrete signals, to obtain the first frequency spectrum.

16. The signal analyzing method as claimed in claim 10, wherein a sampling unit is arranged to sample the filtered signal to obtain the discrete signal according to a sampling frequency, and a band pass filter is arranged to filter the input signal to obtain the filtered signal, wherein a bandwidth range of the band pass filter is from 2/N times that of the sampling frequency to ½ times that of the sampling frequency.

17. The signal analyzing method as claimed in claim 10, wherein the input signal is a vibration signal, an audio signal or a radio frequency signal.
